(19) United States
(12) Patent Application Publication
(10) Pub. No.: US 2021/0367006 A1
(43) Pub. Date: Nov. 25, 2021

(54) Camera in Display

(71) Applicant: Telefonaktiebolaget LM Ericsson (publ), Stockholm (SE)

(72) Inventors: Alexander Hunt, Tygelsjö (SE); Fredrik Dahlgren, Lund (SE)

(21) Appl. No.: 16/878,235

(22) Filed: May 19, 2020

(51) Int. Cl. H01L 27/32; G06F 3/01; G06F 3/041; H04N 5/225; G06K 9/00; H04N 5/232; G09G 3/3208

(52) U.S. Cl. CPC H01L 27/3234; G06F 3/013; G06F 3/0412; G09G 2360/144; G06K 9/00281; H04N 5/23212; G09G 3/3208; H04N 5/2257

(57) ABSTRACT

A display with both sensing diodes and emitting diodes constructed on a common backplane, where each sensing diode includes a lens having a focal length configured for a particular imaging distance from the display is presented herein. The sensing diodes may be used to detect environmental characteristics, e.g., light levels, presence of a user, etc., where the sensing and/or emitting diodes are then configured responsive to the detected environmental characteristics.

### BACKGROUND

Traditional displays use light emitting diodes to emit combinations of light and colors responsive to input signals to output an image on the display. As such, displays were traditionally output devices. Increasingly, however, displays also operate as input devices, and thus have dual input/output functions. To that end, conventional displays include or cooperatively operate with image detection devices to receive user input. For example, some handheld devices have built-in cameras that cooperatively operate with the display, and typically have fixed direction, location, and/or focal lengths. Other displays may have built-in photosensors. In either case, such image detection devices may be used to provide valuable input to the corresponding device, e.g., facial recognition input, touchscreen detection, gaze direction input, environmental light level input, etc.

Conventional implementations of dual input/output displays have experienced multiple problems. For example, adding a separate camera to cooperatively operate with the display may negatively impact the overall size of the device, while using an existing device camera for such a purpose may overly constrain the location(s) within the device for such a built-in camera and/or may require more complexity than otherwise necessary for display input functions. While displays with built-in sensors may address some of these issues, current implementations of such built-in sensors have other issues. For example, some conventional built-in sensor implementations require the photosensors to be shielded from the emitting diodes for proper operation, while other conventional built-in sensor implementations, e.g., that use LCD panels, must account for the photosensors' response to the LCD backlight. Such additional considerations typically increase the overall size and/or complexity of the display.

Thus, there remains a need for improved display technologies that provide both image input and output capabilities for the latest electronic devices.

### SUMMARY

The solution presented herein constructs both sensing diodes and emitting diodes on a common backplane, where each sensing diode includes a lens having a focal length configured for a particular imaging distance from the display. The sensing diodes may be used to detect environmental characteristics, e.g., light levels, presence of a user, etc., where the sensing and/or emitting diodes are then configured responsive to the detected environmental characteristics.

One exemplary embodiment comprises a display for an electronic device, where the display comprises a backplane, a plurality of diodes, and a control circuit. The backplane comprises an active control matrix. The plurality of diodes are constructed on the backplane to operatively connect to the active control matrix. Further, the plurality of diodes comprise a plurality of sensing diodes integrated with a plurality of emitting diodes. The display further includes a lens for each of the plurality of sensing diodes, where each lens is proximate a top surface of the corresponding sensing diode and has a focal length. The control circuit is operatively connected to the active control matrix and is configured to activate one or more of the plurality of sensing diodes via the active control matrix to detect one or more characteristics of an environment proximate the display. The control circuit is further configured to configure the plurality of diodes responsive to the detected one or more characteristics of the environment.

In some embodiments, the plurality of diodes are constructed on the backplane according to diode patterns, where each diode pattern comprises at least one of the plurality of sensing diodes and multiple ones of the plurality of emitting diodes. For example, each diode pattern may comprises one of the plurality of sensing diodes and a subset of emitting diodes comprising one color-specific emitting diode for each of a plurality of colors. In another example, each diode pattern comprises one of the plurality of sensing diodes and plurality of subsets of emitting diodes, where each of the plurality of subsets of emitting diodes comprises one color-specific emitting diode for each of a plurality of colors. In yet another example, each diode pattern comprises a subset of emitting diodes comprising one color-specific emitting diode for each of a plurality of colors, the color-specific emitting diode for one of the plurality of colors being separated from the color-specific emitting diode for another one of the plurality of colors by one of the plurality of sensing diodes. In another exemplary embodiment, each diode pattern comprises a subset of emitting diodes comprising a plurality of groups of color-specific emitting diodes, each group of color-specific emitting diodes comprising a plurality of emitting diodes for one of a plurality of colors, wherein the group of color-specific emitting diodes for one of the plurality of colors is separated from the group of color-specific emitting diodes for another one of the plurality of colors by one of the plurality of sensing diodes.

One exemplary embodiment comprises an electronic device comprising a communication circuit and a display. The communication circuit is configured to transmit and receive data via a communication network. The display comprises a backplane, a plurality of diodes, and a control circuit. The backplane comprises an active control matrix. The plurality of diodes are constructed on the backplane to operatively connect to the active control matrix. Further, the plurality of diodes comprise a plurality of sensing diodes integrated with a plurality of emitting diodes. The display further includes a lens for each of the plurality of sensing diodes, where each lens is proximate a top surface of the corresponding sensing diode and has a focal length. The control circuit is operatively connected to the active control matrix and is configured to activate one or more of the plurality of sensing diodes via the active control matrix to detect one or more characteristics of an environment proximate the display. The control circuit is further configured to configure the plurality of diodes responsive to the detected one or more characteristics of the environment.

In some exemplary embodiments, the electronic device comprises a mobile device, e.g., a smart watch, a cellular telephone or other mobile communication device, etc., where the communication circuit is configured to transmit and receive data via a wireless communication network. In other exemplary embodiments, the electronic device comprises a television or computer monitor.

One exemplary embodiment comprises a method of controlling a display for an electronic device, where the display comprises a backplane comprising an active control matrix, and a plurality of diodes constructed on the backplane to operatively connect to the active control matrix. The plurality of diodes comprise a plurality of sensing diodes integrated with a plurality of emitting diodes, and a lens for each of the plurality of sensing diodes. Each lens is proximate a top surface of the corresponding sensing diode and has a focal length. The method comprises activating one or more of the plurality of sensing diodes via the active control matrix to detect one or more characteristics of an environment proximate the display. The method further comprises configuring the plurality of diodes responsive to the detected one or more characteristics of the environment.

### BRIEF DESCRIPTION OF THE DRAWINGS

FIG. 1 shows a display according to exemplary embodiments of the solution presented herein.

FIG. 2 shows a method of controlling a display according to exemplary embodiments of the solution presented herein.

FIGS. 3A-3D show photodiode patterns according to exemplary embodiments of the solution presented herein.

FIG. 4 shows photodiode patterns according to exemplary embodiments of the solution presented herein.

FIGS. 5A-5B show photodiode patterns according to exemplary embodiments of the solution presented herein.

FIGS. 6A-6B show photodiode patterns according to exemplary embodiments of the solution presented herein.

FIG. 7 shows a block diagram of an electronic device according to exemplary embodiments of the solution presented herein.

FIG. 8 shows an exemplary electronic device according to exemplary embodiments of the solution presented herein.

### DETAILED DESCRIPTION

The solution presented herein provides a dual input/output display by constructing a display backplane that integrates emitting diodes with sensing diodes. In so doing, the solution presented herein avoids many of the problems associated with conventional input/output displays.

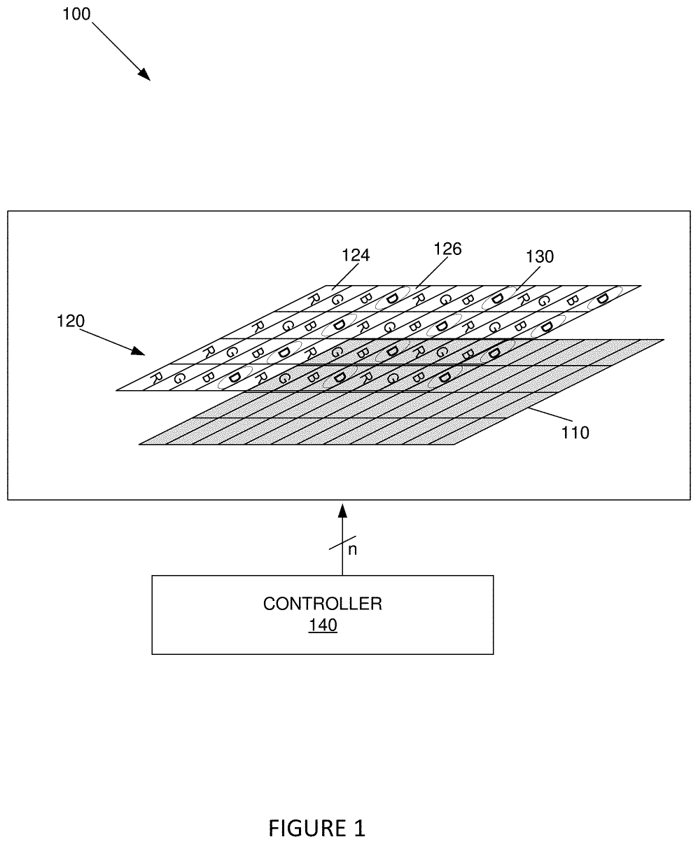

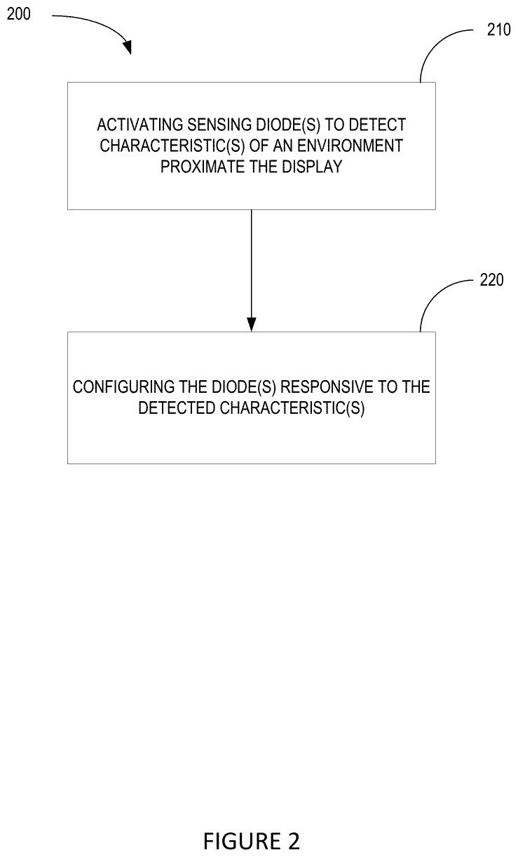

FIG. 1 shows an exemplary display 100, while FIG. 2 shows an exemplary method 200 of controlling the display 100, according to the solution presented herein. Display 100 includes a plurality of diodes 120 constructed on a backplane 110, e.g., an Organic Light Emitting Diode (OLED) produced by, e.g., amorphous Silicon (a-Si), Low Temperature Polycrystalline Silicon (LTPS), Indium Gallium Zinc Oxide (IGZO), or similar technologies. The plurality of diodes 120 includes a plurality of emitting diodes 124 integrated with a plurality of sensing diodes 126, where each sensing diode 126 has an associated lens 130. The method 200 comprises activating one or more of the plurality of sensing diodes 126 via the active control matrix of the backplane 110 to detect one or more characteristics of an environment proximate the display 100 (block 210). Method 200 further comprises configuring the plurality of diodes 120 responsive to the detected one or more characteristics of the environment (block 220). By controlling an active control matrix of the backplane 110, e.g., via control circuit 140, the solution presented herein controls how and when the emitting diodes 124 emit or output light, as well as how and when the sensing diodes 126 sense light.

A lens 130 is disposed proximate each sensing diode 126 to facilitate the usefulness of the information collected by the sensing diodes 126, as well as to facilitate the intended application of the collected information, e.g., privacy limitations. Exemplary lenses 130 include, but are not limited to, micro lenses, liquid lens, etc. The lens 130 may be any size or shape suitable for the corresponding sensing diode 126. For example, a lens 130 for a rectangular sensing diode 126 may be elliptical while a lens 130 for a square sensing diode 126 may be circular. It will be appreciated that lenses 130 may be implemented as individual lenses, where each lens 130 is proximate the corresponding sensing diode 126, or that the lenses may be implemented as a lens array for the display 100, where the lens array includes a lens 130 at each location in display 100 corresponding to the sensing diode 126. While lens 130 may abut a surface of a corresponding sensing diode 126 in some embodiments, in other embodiments, the lens 130 may be spaced from the surface of the corresponding sensing diode 126, e.g., by an adhesive, air, liquid, etc. In some exemplary embodiments, the lens 130 may abut an inside of a cover of the display 100 to provide space between the lens 130 and the sensing diode 126. Further, each lens 130 may have a simple, two surface lens structure, or may comprise a multi-stack lens structure. Lenses 130 may be manufactured using any known technique, e.g., nanolithography, wafer level optics, etc.

The lenses 130 move the focus of an image captured by the corresponding sensing diode 126 from the surface of the display 100 to a designed focus range in space. The display 100 is designed to cover a particular Field of View (FOV), where each sensing diode/lens combination has a FOV that covers a small portion of the full FOV of the display 100. Depending on the density of the integration of the sensing diodes 126 in display 100, each sensing diode's FOV will overlap some amount with a nearby sensing diode's FOV. Moving the focus range closer to the display 100 makes the area covered by each sensing diode/lens combination smaller, while moving the focus range further away makes the area of each sensing diode/lens combination larger. Thus, each lens 130 moves the focus away from the surface of the display 100 to a focus range in space relative to the display 100, where this focus range may provide a more usable distance, such as appropriate for facial or image recognition. For example, a suitable viewing distance for viewing a smart watch device 10 is 250-400 mm, thus, the lenses 130 may be configured to focus at focus range 250-400 mm from the display 100 so as to better capture an image of the user's face.

In some embodiments, each lens 130 has the same focal length. Such implementations may be appropriate for smaller displays, e.g., mobile device displays, where the distance between the display 100 and designed focus range is approximately the same for all sensing diodes 126 regardless of their location in the display 100. In other embodiments, e.g., those with larger displays, e.g., televisions or monitors, where the distance between the sensing diodes 126 and the designed focus range varies depending on the location of each sensing diode 126, different lenses 130 may have different focal lengths. Regardless, the solution presented herein includes the lenses 130 to improve the images captured by the sensing diodes 126.

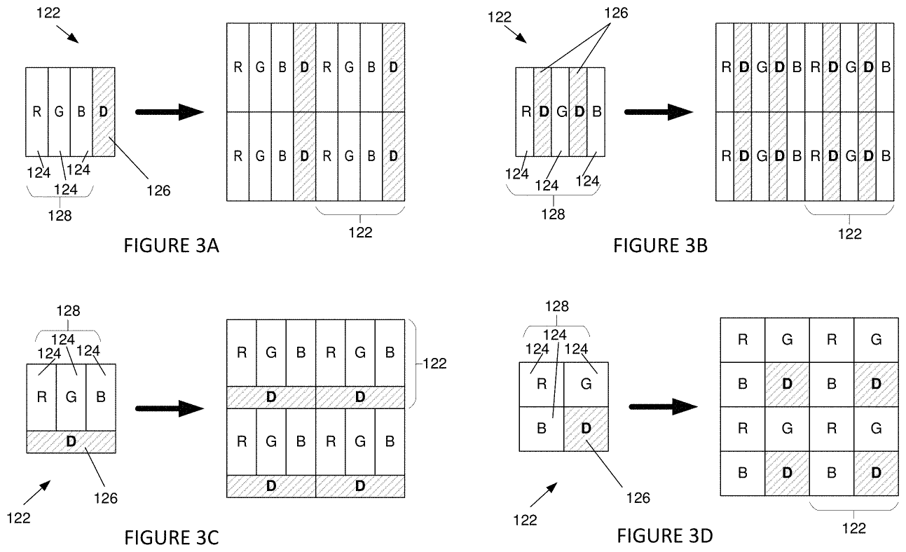

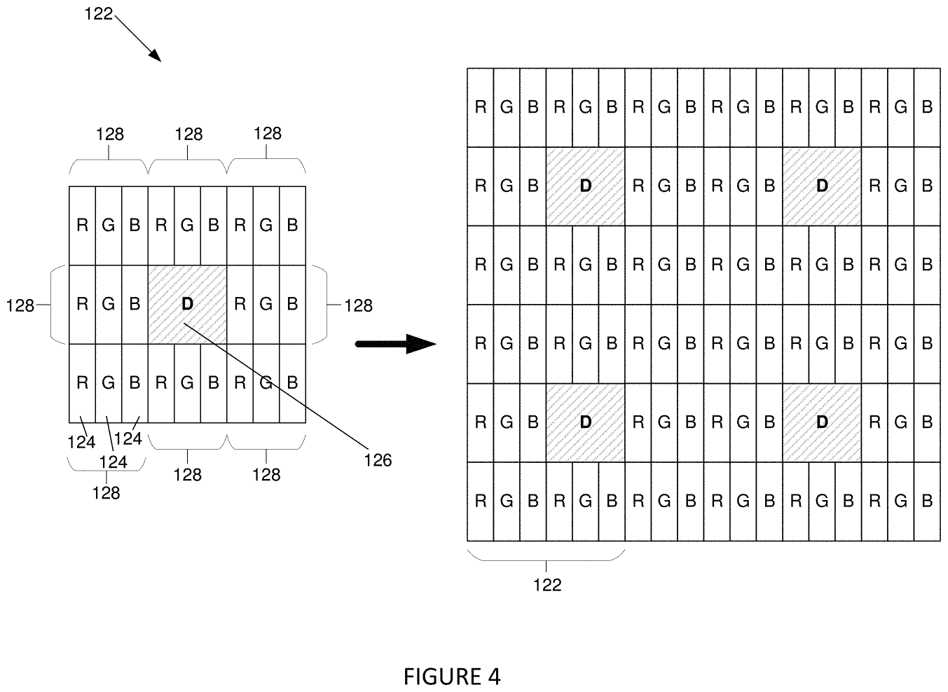

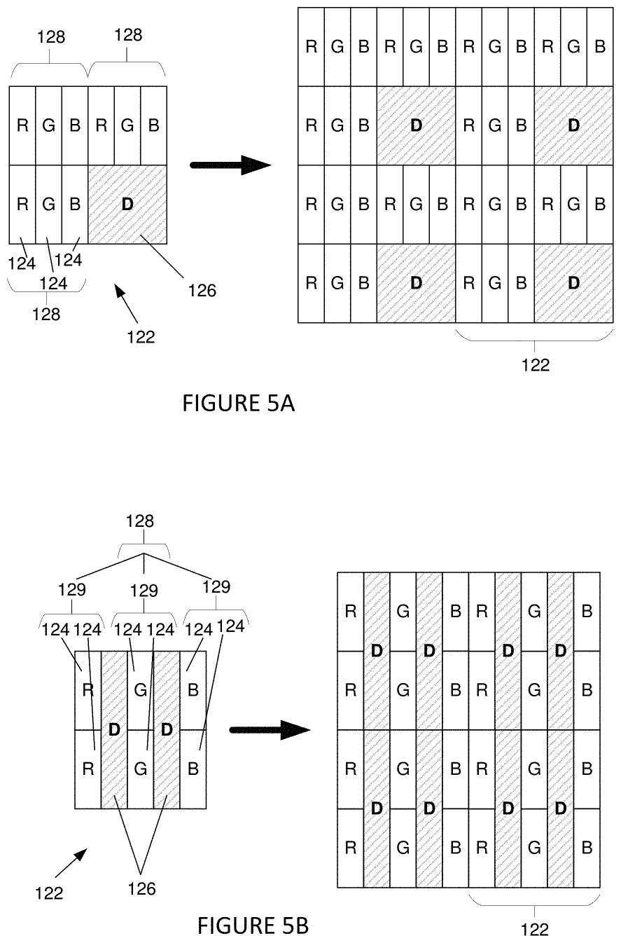

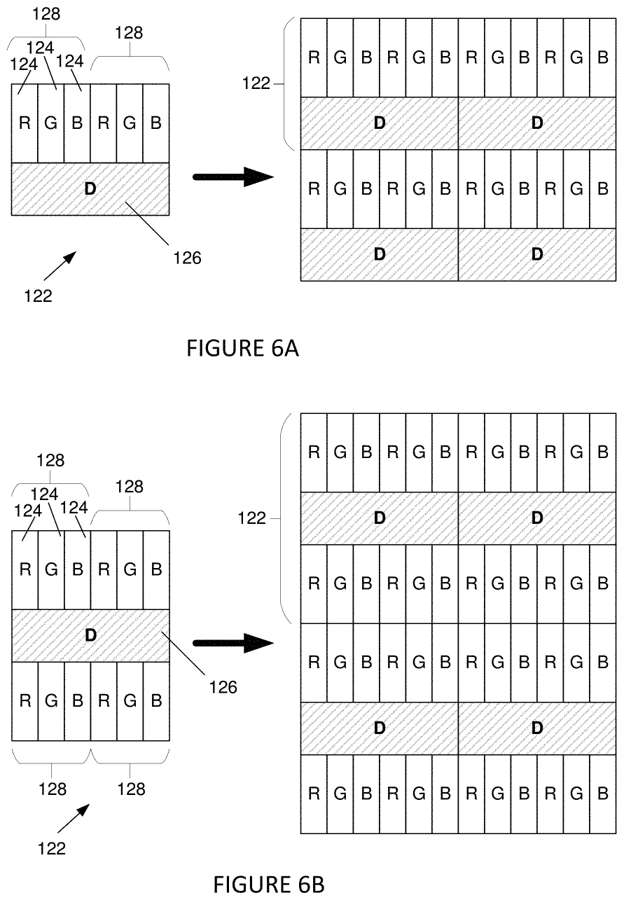

The emitting diodes 124 and sensing diodes 126 may be integrated onto the backplane 110 according to any known or preferred diode pattern 122. FIGS. 3-6 show multiple examples of different diode patterns 122, which should be viewed as exemplary and non-limiting. In some exemplary embodiments, e.g., as shown in FIGS. 3A-3D, the emitting diodes 124 and the sensing diodes 126 in each diode pattern 122 are all the same size and/or shape. In other exemplary embodiments, as shown in FIGS. 4, 5A-5B, and 6A-6B, the sensing diodes 126 and the emitting diodes 124 in each diode pattern 122 are different sizes and/or different shapes. Further, while FIGS. 4-6 show embodiments where the sensing diode 126 is a single sensing diode 126 that is larger than the emitting diodes 124 in the pattern 122, it will be appreciated that a larger sensing diode 126 may alternatively be implemented by multiple smaller sensing diodes 126. For example, the larger sensing diode 126 of the pattern 122 in FIG. 4 or in FIG. 5A could be implemented by three sensing diodes 126, all the same size as the corresponding emitting diodes 124, or could be implemented by multiple sensing diodes 126 smaller/larger than the emitting diodes 124. Further, it will be appreciated that while display 100 may be constructed with multiple ones of a particular pattern 122 throughout the display 100, or multiple ones of a particular pattern 122 in certain sections of the display 100, in some embodiments different sections of the display 100 may be constructed with different patterns 122. For example, a central section of a display 100 may be constructed with multiple ones of the pattern 122 in FIG. 3D while the surrounding edge sections of that display may be constructed with multiple ones of pattern 122 in FIG. 6B. It will further be appreciated that while some sections of the display 100 may be constructed with one or more particular patterns 122, other sections may be constructed only with emitting diodes 124. Thus, the solution presented herein does not require that an entire display 100 be constructed with patterns 122, or that a display 100 be constructed with all the same pattern 122.

Each diode pattern 122 is made up of a plurality of emitting diodes 124, e.g., a subset 128 of emitting diodes 124, and at least one sensing diode 126, arranged according to a predetermined pattern. FIGS. 3-6 show exemplary diode patterns 122 where each subset 128 of emitting diodes 124 comprises multiple color-specific emitting diodes 124, e.g., at least one red “R” emitting diode 124, at least one green “G” emitting diode 124, and at least one blue “B” emitting diode 124. It will be appreciated, however, that the solution presented herein may use any emitting diode technology, and is not limited to the R, G, B options shown in the figures. However, for simplicity, the following describes the solution in terms of emitting diodes 124 or color-specific emitting diodes 124 or subsets 128 of emitting diodes 124 without requiring the explicit red, green, and blue diodes of the figures, without limiting any of the emitting diodes 124 to a single color or to a particular color, and without requiring the emitting diode subsets 128 to be arranged with the specific color arrangements shown in FIGS. 3-6. It will further be appreciated that filters may be used with white light emitting diodes to create the desired colors and/or color patterns.

The exemplary embodiments of FIGS. 3A-3D demonstrate different diode patterns 122 of equal-sized diodes 124, 126. It will be appreciated that while FIGS. 3A-3C show rectangular diodes 124, 126 and FIG. 3D shows square diodes, any of the embodiments of FIGS. 3A-3C may alternatively use square diodes (or diodes of any desired shape), and the embodiment of FIG. 3D may alternatively use rectangular diodes (or diodes of any desired shape). As such, the diodes 124, 126 of the examples of FIGS. 3A-3D are not limited to the specific shapes shown in FIGS. 3A-3D.

In FIG. 3A, which corresponds to the exemplary display 100 of FIG. 1, the pattern 122 sequentially arranges a subset 128 of vertically oriented color-specific emitting diodes 124 adjacent to each other, followed by the sensing diode 126, while the pattern 122 of FIG. 3B alternates an emitting diode 124 and a sensing diode 126 for each color-specific emitting diode 124 in the display 100. As a result, a display 100 constructed with these diode patterns 122 includes “stripes” of sensing diodes 126 and “stripes” of color-specific emitting diodes 124, where each of the emitting and sensing diode stripes have the same orientation. Depending on the orientation of the display 100, these “stripes” may comprise vertical stripes (as shown) or horizontal stripes. A display constructed with the pattern 122 of FIG. 3C also results in a display 100 with “stripes” of sensing diodes 126, but in this example, the orientation of each sensing diode 126 is perpendicular to the orientation of the emitting diodes 124 in the emitting diode subset 128, resulting in stripes of sensing diodes 126 that interrupt the stripes of color-specific emitting diodes 124.

In yet another exemplary embodiment, the sensing and emitting diodes 124, 126 may be arranged in a grid pattern 122, as shown in FIG. 3D. As a result, individual sensing diodes 126 are dispersed throughout display 100, where each sensing diode 126 is surrounded by a subset 128 of multiple emitting diodes 124. It will be appreciated that while FIG. 3D shows the sensing diode 126 in the lower right corner of the pattern 122, sensing diode 126 may alternatively be placed in any diode location of the pattern 122.

FIG. 4 shows an exemplary pattern 122, where the sensing diodes 126 are larger (and a different shape) than the emitting diodes 124, and where the sensing diode 126 within each pattern 122 is surrounded by a subset 128 of emitting diodes 124. As with the example of FIG. 3D, a display 100 constructed using the pattern 122 of FIG. 4 results in a display 100 with a grid pattern, where individual sensing diodes 126 are dispersed throughout the display 100. In this exemplary embodiment, however, the sensing diode 126 in each pattern 122 abuts only those emitting diodes 124 that are part of the same pattern 122. While a display 100 constructed with the pattern 122 of FIG. 4 has fewer sensing diodes 126 than would be achieved with the pattern 122 of FIG. 3D, each sensing diode 126 in the display constructed with the pattern 122 of FIG. 4 has a higher sensitivity due to its larger surface area.

FIG. 5A shows another exemplary pattern 122, where the sensing diode 126 in each pattern 122 is larger (and a different shape) than the emitting diodes 124. In this example, the sensing diode 126 within each pattern 122 is constructed in one corner of the pattern 122, e.g., the bottom right corner. It will be appreciated that placing the sensing diode 126 in the bottom right corner of the pattern 122 is an exemplary, non-limiting option. As with the example of FIG. 3D, a display 100 constructed using the pattern 122 of FIG. 5 results in a grid pattern of diodes, where individual sensing diodes 126 are dispersed throughout display 100. In this exemplary embodiment, however, the sensing diode 126 is larger than the emitting diodes 124 of the pattern 122. Thus, constructing a display 100 using the pattern 122 of FIG. 5A results in a display 100 with fewer sensing diodes 126 than would be achieved with the pattern of FIG. 3D, but with more sensing diodes 126 than would be achieved with the pattern of FIG. 4, where each sensing diode 126 in the pattern 122 of FIG. 5A has a higher sensitivity than the sensing diodes 126 of the pattern 122 of FIG. 3D due to its larger surface area.

FIG. 5B shows an exemplary pattern 122 where the subset 128 of emitting diodes 124 includes columns (or groups) of vertically oriented color-specific emitting diodes 124 that alternate with columns (or groups) of vertically oriented sensing diodes 126, where each sensing diode 126 is twice the size of the emitting diodes 124. As a result of this pattern 122, the resulting display 100 includes “stripes” of sensing diodes 126 and “stripes” of color-specific emitting diodes, where each of the emitting and sensing diode stripes have the same orientation. Depending on the orientation of the display 100, these “stripes” may comprise vertical stripes (as shown) or horizontal stripes.

FIGS. 6A and 6B also show patterns 122 that result in a display 100 with “stripes” of sensing diodes 126, but in these examples, the orientation of each sensing diode 126 is perpendicular to the orientation of the subset 128 of emitting diodes 124, resulting in stripes of sensing diodes 126 that interrupt the stripes of color-specific emitting diodes 124. Unlike the example pattern 122 of FIG. 3C, the example patterns 122 of FIGS. 6A and 6B do not have equal sized sensing and emitting diodes 124, 126, resulting in a display 100 with fewer, but more sensitive, sensing diodes 126, where a display 100 constructed with the pattern 122 of FIG. 6B has fewer sensing diodes 126 than the display 100 constructed with the pattern 122 of FIG. 6A.

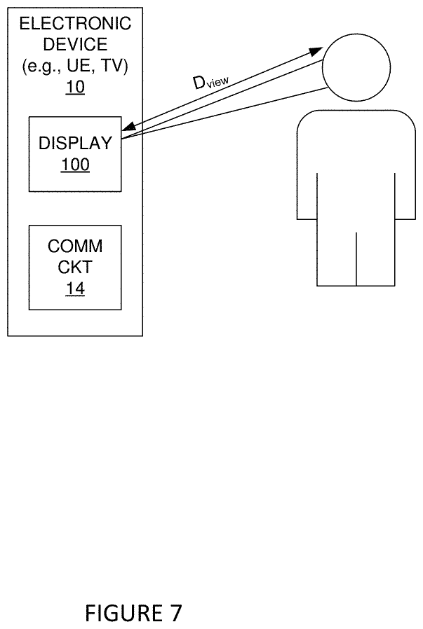

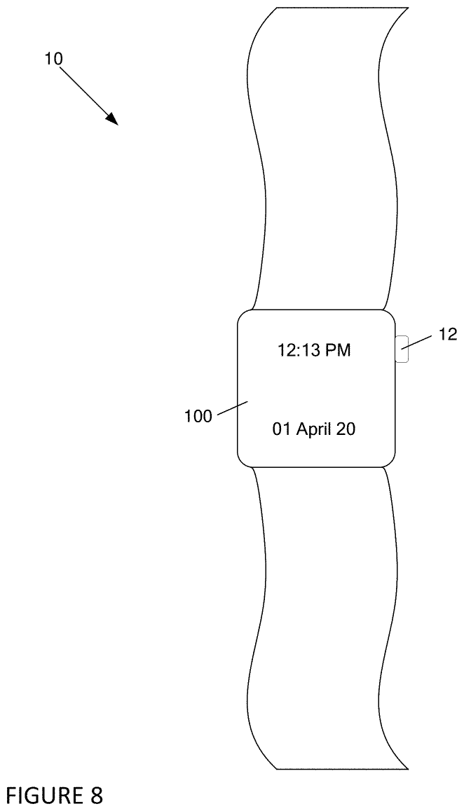

Display 100 may be part of any electronic device 10, and is particularly useful for those electronic devices 10 having displays that receive user input, as well as output images and other information. FIG. 7 shows an exemplary electronic device 10 comprising the display 100 and a communication circuit 14. While not explicitly shown, it will be appreciated that electronic device 10 may include other components necessary for its overall operation, e.g., other input or output devices (e.g., cameras or sensing devices, microphones, speakers, etc.), other processing circuits, memory to store instructions, received data, or data to be transmitted, etc. Exemplary electronic devices 10 include, but are not limited to, mobile devices (e.g., smart phones, smart watches (FIG. 8), tablets, etc.), televisions, computer monitors, etc. In each case, the lens 130 included for each of the sensing diodes 126 in the display 100 is configured with a focal length selected for a distance between the display 100 and designed focus range in space, e.g., the expected viewing distance D_{view} from the display 100 to the user's face. For example, when the electronic device 10 is a smart watch, e.g., as shown in FIG. 8, D_{view} is the distance between the user's face and the watch when the user is holding the wrist up for viewing the watch. Alternatively, when the electronic device is a computer monitor, D_{view} is the distance between the user's face and the monitor, e.g., when the monitor is still close enough for the user to touch the screen or when the monitor is at a normal viewing distance.

The communication circuit 14 comprises any circuitry configured for receiving and/or sending communication signals associated with operation of the electronic device 10. For example, when the electronic device 10 is a wireless electronic device, the communication circuit 14 may comprise any wireless communication circuitry and/or wireless interface configured for any known wireless communications, e.g., cellular communications, WiFi communications, Bluetooth communications, etc. In another example, when the electronic device 10 is a wired electronic device, the communication circuit 14 may comprise any communication circuitry and/or interface configured for any known wired communications, e.g., cable communications, wired internet communications, fiber-optic cable communications, etc.

Regardless of the type of electronic device 10 or the pattern of the sensing and emitting diodes 124, 126 in the display 100, the control circuit 140 for the display 100 configures the plurality of diodes 120 responsive to the environmental characteristic(s) detected by the sensing diodes 126. To that end, the control circuit 140 may include a Graphics Processing Unit (GPU) to control the diodes 120 and/or to handle general GPU tasks. The configuration provided by the control circuit 140 may include a configuration of all of the diodes 120, a configuration of all or some emitting diodes 124, a configuration of all or some sensing diodes 126, or a configuration of some of emitting diodes 124 and some sensing diodes 126, e.g., those in a certain location of the display 100. In some circumstances, this configuration may be a calibration, e.g., a calibration of the sensing diodes 126 for subsequent image capturing operations, and/or a configuration of the emitting diodes 124, e.g., for improved display operations.

In one exemplary embodiment, the control circuit 140 configures the plurality of diodes 120 responsive to a detected light condition of the environment. For example, the control circuit 140 may configure the emitting diodes 124 responsive to the detected light condition to enable the user to better view the information output by the display 100.

In other exemplary embodiments, the control circuit 140 may preconfigure or otherwise calibrate the sensing diodes 126 responsive to the detected light condition to set up the appropriate exposure, white balance, etc., for subsequent image capturing operations in the current light condition. This is beneficial because sensing diodes 126 have a limited dynamic range. Thus, changing the sensitivity of the sensing diode(s) 126 responsive to the surrounding light condition improves the ability of each sensing diode 126 to accurately and quickly capture the scene. With conventional cameras, such calibration typically occurs during the first few frames of the viewfinder in an ordinary camera application. This delay, however, would undesirably impact the operation of the display 100 disclosed herein, given the preference to have the sensing diodes 126 capture images without the user being aware. Thus, preconfiguring (or calibrating) the sensing diodes 126 according to the solution presented herein increases the achievable quality of the image as well as the image capture speed (which also depends on the framerate and/or readout speed of the sensing diode(s) 126, as well as whether global or rolling shutter technology is used). For example, this calibration may enable sensing diodes 126 to subsequently capture images in a fraction of a second, e.g., 1/60 sec, which enables the sensing diodes 126 to capture images useful to the operation of the display 100 such that, even when the display 100 is in use, the user will not detect any interruption with the output function of the display 100. Further, for devices 10 having a display 100 that is not flat, e.g., a curved or flexible display, the environment may be different for different parts of the display 100. It will thus be appreciated that the control circuit 140 may be further configured to execute different calibration operations for sensing diodes 126 in different parts of display 100.

While the preconfiguration (or calibration) of the sensing diodes 126 may be implemented as part of a “first use” of the device 10, the sensing diodes 126 may also be calibrated when the display 100 is already in use. This may be done continually by detecting an area of the display 100 having inactive emitting diodes 124, and using the sensing diodes 126 in this area of the display 100 to generate the calibration information necessary to calibrate the sensing diodes 126. If the full display 100 is used for presenting information, then the control circuit 140 may deactivate a portion of the emitting diodes 124 of the display 100 so that the nearby sensing diodes 126 may be used for the calibration, as discussed further below.

In exemplary embodiments, the control circuit 140 may be further configured to process an image captured by the sensing diodes 126. To that end, the control circuit 140 may include image processing circuitry or other processing circuitry necessary to process the captured image. For example, the control circuit 140 may be configured to process a captured image to identify one or more user characteristics, e.g., a presence of a face of a user, facial characteristics of the user, a proximity of the face of the user, a gaze of the user, whether the user is wearing glasses and/or what type of glasses (e.g., distance or reading glasses), etc., from the captured image. The control circuit 140 may use this information to further configure the plurality of diodes 120 to create a more user-specific experience. For example, if the control circuit 140 determines the face in a captured image is that of an authorized user of the electronic device 10, or determines that a gaze of the user is directed at the electronic device 10, the control circuit 140 may activate one or more of the emitting diodes 124 to display personal information, e.g., a personal image, an incoming message, etc. Alternatively, if the control circuit 140 determines the face in a captured image is not that of an authorized user of the electronic device 10 or determines that a gaze of the user is not directed at the electronic device, the control circuit 140 may deactivate one or more of the emitting diodes 124 to prevent information, e.g., personal information, from appearing on the display 100 or may activate one or more of the emitting diodes 124 to only display general information, e.g., time, date, etc. In another example, if the control circuit 140 detects reading glasses on the face of the user, the control circuit 140 may configure the emitting diodes 124 differently than if the control circuit 140 detected distance glasses or no glasses on the face of the user. Further, the control circuit 140 may determine which of a number of authorized users is viewing the display, e.g., whether a child or a particular adult is viewing the display 100, and thus may configure the emitting diodes 124 to account for the vision of the different users and/or to account for parental controls. While the above describes the image processing and subsequent control as all being implemented by the control circuit 140, it will be appreciated that a separate image processing circuit, either one that is part of the display 100 or one that is in the device 10 but operatively connected to the display 100, may perform the image processing analysis and provide the image processing data to the control circuit 140, or may generate a control signal responsive to the image processing data and provide the control signal to the control circuit 140.

When there is a possibility that light from the emitting diodes 124 may interfere with the operation of the sensing diodes 126, the control circuit 140 may further consider the status of the emitting diodes 124, e.g., active or inactive, before activating the sensing diodes 126. For example, the control circuit 140 may configure the plurality of diodes 120 by activating sensing diodes 126 in an area of the display 100 having no currently active emitting diodes 124. In some cases, e.g., before a “first use” of the device 10 when the entire display 100 is inactive, any sensing diodes 126 may be activated. In other cases, the control circuit 140 first determines which sensing diodes 126 are in an inactive part of the display 100, and activates those sensing diodes 126. Alternatively, the control circuit 140 may configure the plurality of diodes 120 by deactivating active emitting diodes 124 in the vicinity of some number of sensing diodes 126 before activating these sensing diodes 126 to capture an image, then deactivating these sensing diodes 126 after the image has been captured, and then reactivating the deactivated emitting diodes 124. It will be appreciated that the deactivated emitting diodes 124 should remain deactivated during the integration time of the sensing diodes 126 being used to capture an image. Because the integration time depends on the light condition of the environment, low light conditions may lengthen the image capture time, and thus may increase the time previously active emitting diodes 124 remain inactive. Regardless, these exemplary embodiments prevent the sensing diodes 126 intended for capturing an image of the environment from experiencing light interference from nearby emitting diodes 124. It will be appreciated that this selective activation of the sensing diodes 124 in inactive areas of the display 100 may occur before and/or after the sensing diodes 126 are preconfigured.

Other exemplary embodiments include further configuring the control circuit 140 to control the plurality of diodes 120 responsive to user input, e.g., activation of a push button 12 on the electronic device 10, user contact with the display 100, user motion, etc., and/or responsive to a notification, e.g., a notification of an incoming message, calendar event, reminder, etc. For example, upon receipt of user input, the control circuit 140 may activate one or more sensor diodes 126 to capture environmental information, and then configure some number of the emitting diodes 124 responsive to the captured environmental information to output information to the user, e.g., the time, part or all of an incoming message, etc., as disclosed herein.

In one exemplary embodiment, the device 10 is a smartwatch, as shown in FIG. 8. In this embodiment, the lenses 130 of the sensing diodes 126 have a focal length associated with a typical reading range, e.g., 250-400 mm. When the display 100 is activated, e.g., by movement of the device 10, a user touching the display 100, the user pressing a button 12, etc., the sensing diodes 126 are activated to capture light information (e.g., for subsequent calibration) and/or an image to enable the device 10 to determine whether the user is looking at the display 100 (gaze detection) and/or if the captured image indicates only the user is looking at the display 100, whether the user is wearing eyewear, etc. If the user is looking at the display 100, the emitting diodes 124 may be configured to output private content (e.g., content of a message); otherwise, the emitting diodes 124 may be configured to only show generic information, e.g., the standard background content, an indication that a new message arrived, etc. Alternatively or additionally, if the user is wearing eyewear and/or if the user is wearing a particularly type of eyewear (for example if the user has two different pair pf glasses), the emitting diodes 124 may be configured to adjust the output of the display accordingly.

The solution presented herein has several advantages over conventional input/output display solutions. For example, by integrating sensor diodes 126 with the emitting diodes 124 onto a common backplane with a common active control matrix, and by controlling which sensor diodes 126 capture the environmental information, the solution presented herein enables the capturing of the environmental information without interference from active emitting diodes 124, and provides a solution that does not take up any more space than a display constructed with only emitting diodes 124. Further, the solution presented herein provides quick control of all of the diodes 120, which enables the display 100 to quickly gather information, e.g., via sensing diode(s) 126, and control the operation of the diodes 120 in general without any perceivable disruption to the output of display data to the user. In addition, by considering the gaze and/or identity of the user, the solution presented herein provides an additional privacy feature not achievable with conventional displays. Further, by considering whether a user is wearing glasses and/or the type of glasses and/or which authorized user is viewing the display, the solution presented herein enables the displayed output to be configured for different visual circumstances and/or different users. Also, by integrating the sensing diodes 126 with the emitting diodes 124 throughout the display 100, the solution presented herein accommodates all types of displays, including curved displays, flexible displays, etc. It will be appreciated that with curved or flexible displays, the sensing diodes 126 activated for environmental characteristics may be selected to be those sensing diode(s) 126 in the portion of the display 100 expected to be subsequently used, e.g., in the portion of the display 100 facing the user. Further, because the images typically being captured by the sensing diodes 126, e.g., gaze direction, facial recognition, etc., do not need to be high resolution, the sensing diodes 126 integrated with the emitting diodes 124 may have a lower resolution, and thus consume less power, than sensors conventionally used for cameras or other high resolution image capturing operations.

The present invention may, of course, be carried out in other ways than those specifically set forth herein without departing from essential characteristics of the invention. The present embodiments are to be considered in all respects as illustrative and not restrictive, and all changes coming within the meaning and equivalency range of the appended claims are intended to be embraced therein.

What is claimed is:

1. A display for an electronic device, the display comprising:
a backplane comprising an active control matrix;
a plurality of diodes constructed on the backplane to operatively connect to the active control matrix, the plurality of diodes comprising a plurality of sensing diodes integrated with a plurality of emitting diodes;
a lens for each of the plurality of sensing diodes, each lens proximate a top surface of the corresponding sensing diode and having a focal length; and
a control circuit operatively connected to the active control matrix and configured to:
activate one or more of the plurality of sensing diodes via the active control matrix to detect one or more characteristics of an environment proximate the display; and
configure the plurality of diodes responsive to the detected one or more characteristics of the environment.

2. The display of claim 1 wherein the plurality of diodes are constructed on the backplane according to diode patterns, each diode pattern comprising at least one of the plurality of sensing diodes and multiple ones of the plurality of emitting diodes.

3. The display of claim 1 wherein each lens has the same focal length.

4. The display of claim 1 wherein the focal length of each lens is configured responsive to a viewing distance (D_{view}) between the display and a focus range in space relative to the electronic device.

5. The display of claim 4 wherein the focal length for each lens is configured responsive to the viewing distance (D_{view}) and a location of the corresponding sensing diode on the backplane.

6. The display of claim 1 wherein the control circuit configures the plurality of diodes responsive to the detected one or more characteristics of the environment by preconfiguring the plurality of sensing diodes responsive to a light condition of the environment.

7. The display of claim 6 wherein the control circuit further configures the plurality of diodes responsive to the detected one or more characteristics of the environment by:
deactivating activated ones of the plurality of emitting diodes proximate the preconfigured plurality of sensing diodes;
activating the preconfigured sensing diodes to capture an image of the environment proximate the display while the proximate emitting diodes are deactivated;
deactivating the preconfigured sensing diodes; and
reactivating the deactivated ones of the plurality of emitting diodes.

8. The display of claim 1 wherein the control circuit is further configured to identify one or more user characteristics from the captured image.

9. The display of claim 8 wherein the control circuit configures the plurality of diodes by activating one or more of the plurality of emitting diodes responsive to identifying a face of a user of the electronic device in the captured image.

10. The display of claim 9 wherein the control circuit configures the plurality of diodes by activating the one or more of the plurality of emitting diodes responsive to identifying that a gaze of the face of the user of the electronic device in the captured image is directed towards the display.

11. The display of claim 8 wherein the control circuit configures the plurality of diodes by configuring one or more of the plurality of emitting diodes responsive to identifying a type of glasses worn by, or absent from, a face of a user of the electronic device in the captured image.

12. The display of claim 8 wherein the control circuit configures the plurality of diodes by deactivating any activated emitting diodes responsive to identifying a face in the captured image that is not a user of the electronic device.

13. The display of claim 1 wherein the control circuit is further configured to control the plurality of diodes responsive to user input comprising at least one of user activation of a push button of the electronic device, user contact with the display, and user motion.

14. The display of claim 1 wherein the control circuit activates the one or more of the plurality of sensing diodes by:
identifying one or more sensing diodes proximate inactive ones of the plurality of emitting diodes; and
activating the identified one or more sensing diodes.

15. An electronic device comprising:
a communication circuit configured to transmit and receive data via a communication network; and
a display comprising:
a backplane comprising an active control matrix;
a plurality of diodes constructed on the backplane to operatively connect to the active control matrix, the plurality of diodes comprising a plurality of sensing diodes integrated with a plurality of emitting diodes;
a lens for each of the plurality of sensing diodes, each lens proximate a top surface of the corresponding sensing diode and having a focal length; and
a control circuit operatively connected to the active control matrix and configured to:
activate one or more of the plurality of sensing diodes via the active control matrix to detect one or more characteristics of an environment proximate the display; and
configure the plurality of diodes responsive to the detected one or more characteristics of the environment.

16. The electronic device of claim 15 wherein the electronic device comprises a smart watch, and wherein the communication circuit is configured to transmit and receive data via a wireless communication network.

17. The electronic device of claim 15 wherein the electronic device comprises a mobile communication device, and wherein the communication circuit is configured to transmit and receive data via a wireless communication network.

18. The electronic device of claim 15 wherein the electronic device comprises a television.

19. A method of controlling a display for an electronic device, the display comprising a backplane comprising an active control matrix, a plurality of diodes constructed on the backplane to operatively connect to the active control matrix, the plurality of diodes comprising a plurality of sensing diodes integrated with a plurality of emitting diodes, and a lens for each of the plurality of sensing diodes, each lens proximate a top surface of the corresponding sensing diode and having a focal length, the method comprising:
activating one or more of the plurality of sensing diodes via the active control matrix to detect one or more characteristics of an environment proximate the display; and
configuring the plurality of diodes responsive to the detected one or more characteristics of the environment.

20. The method of claim 19 wherein the configuring the plurality of diodes responsive to the detected one or more characteristics of the environment comprises preconfiguring the plurality of sensing diodes responsive to a light condition of the environment.

21. The method of claim 20 wherein the configuring the plurality of diodes responsive to the detected one or more characteristics of the environment comprises:
deactivating activated ones of the plurality of emitting diodes proximate the preconfigured plurality of sensing diodes;
activating the preconfigured sensing diodes to capture an image of the environment proximate the display while the proximate emitting diodes are deactivated;
deactivating the preconfigured sensing diodes; and
reactivating the deactivated ones of the plurality of emitting diodes.

22. The method of claim 19 wherein further comprising identifying one or more user characteristics from the captured image.

23. The method of claim 22 wherein the configuring the plurality of diodes comprises activating one or more of the plurality of emitting diodes responsive to identifying a face of a user of the electronic device in the captured image.

24. The method of claim 23 wherein the configuring the plurality of diodes comprises activating the one or more of the plurality of emitting diodes responsive to identifying that a gaze of the face of the user of the electronic device in the captured image is directed towards the display.

25. The method of claim 22 wherein the configuring the plurality of diodes comprises configuring one or more of the plurality of emitting diodes responsive to identifying a type of glasses worn by, or absent from, a face of a user of the electronic device in the captured image.

26. The method of claim 22 wherein the configuring the plurality of diodes comprises deactivating any activated emitting diodes responsive to identifying a face in the captured image that is not a user of the electronic device.

27. The method of claim 19 wherein further comprising controlling the plurality of diodes responsive to user input comprising at least one of user activation of a push button of the electronic device, user contact with the display, and user motion.

28. The method of claim 19 wherein the activating the one or more of the plurality of sensing diodes comprises:
identifying one or more sensing diodes proximate inactive ones of the plurality of emitting diodes; and
activating the identified one or more sensing diodes.
